(19) United States
(12) Patent Application Publication
(10) Pub. No.: US 2005/0283710 A1
(43) Pub. Date: Dec. 22, 2005

(54) Coding and decoding for rate matching in data transmission

(76) Inventor: Stefano Olivieri, MILANO (IT)

Correspondence Address: PHILIPS INTELLECTUAL PROPERTY & STANDARDS, P.O. BOX 3001, BRIARCLIFF MANOR, NY, 10510, US

(21) Appl. No.: 10/523,154

(22) PCT Filed: Jul. 16, 2003
(86) PCT No.: PCT/IB03/03250

§ 371 Date: Jan. 27, 2005

(30) Foreign Application Priority Data
Aug. 1, 2002 (EP) 02078153.0

(51) Int. Cl. H03M 13/00

(52) U.S. Cl. 714/759

(57) ABSTRACT

Information is encoded according to an error protecting code. The coding rate is dynamically selected. In an interleaving and puncturing unit the information symbols and parity symbols are interleaved with a predetermined interleaving scheme for protection against burst errors during transmission. The interleaved parity symbols are punctured, puncturing being controlled dynamically by the selected coding rate. The interleaved and punctured symbols are used to transmit modulated information via a transmission channel. By interleaving the information symbols and parity symbols prior to puncturing at the dynamically selected rate it is easier to ensure that during modulation of the punctured symbols optimum use is made of the error properties of the transmission channel.

The invention relates to an information processing apparatus with an error protecting encoders and decoders and to a method of encoding and/or decoding.

U.S. Pat. No. 6,272,183 describes data transmission that uses so-called Turbo-coding. A Turbo-code encoder adds parity bits to information bits in order to enable correction when errors occur in the information bits. During encoding different sets of parity bits are computed, each as a function of the information bits, but each taking account of the information bits in a different interleaved (permuted) sequence. The information bits and parity bits are transmitted via a communication channel and subsequently the parity bits are used to correct errors in the information bits.

The parity bits may be “punctured” (i.e. some of the parity bits may be omitted) prior to transmission. This results in a reduction of the data rate for transmission through the channel at the expense of error correcting capacity. U.S. Pat. No. 6,272,183 describes how the frequency with which parity bits are punctured can be dynamically adapted to support a variable Quality of Service, i.e. to adapt the data rate and the error correcting capacity to dynamical circumstances, such as the availability of bandwidth and the probability of errors.

The effect of errors during transmission may be further reduced by adapting the way in which the bits are modulated so as to minimize the effect of the most likely errors during transmission. For example, one way of transmitting the information bits is the QAM technique, in which groups of bits from the information and parity bits are formed, the values of the bits of each group serving to select a vector with an amplitude and phase of carrier modulation that are to be used to transmit information about the group. In QAM the set of possible modulation vectors that may be selected forms a grid of vectors. A so-called gray labeling technique is preferably used for assigning different modulation vectors to different values of the combination of bits in a group, to ensure that neighboring vectors correspond to different possible values of the combination of bits in the group that differ at one bit position only. Thus, demodulation errors that confuse adjacent vectors will only cause (correctable) one bit errors. When parity bits are used, each group preferably contains one or more parity bits and, if so, it is preferably ensured that that neighboring vectors correspond to different possible values of the bits in the group that differ at one parity bit position only. Thus, demodulation errors that confuse adjacent vectors will mainly cause parity bit errors, which are less damaging than information bit errors.

In a separate development it has been known to use interleaving between encoding and modulation. Interleaving distributes those information bits and parity bits that are to be used together to correct errors over different modulation vectors, which are transmitted separately from one another. A single burst of fading in transmission will only affect modulation symbols that are not separate from one another. As a result interleaving distributes the effect of a burst of fading over bits that are corrected independently of one another, thus preserving a high probability that the effect of the burst can be corrected.

When such post-encoding interleaving is combined with gray labeling one has to keep track of whether the interleaved bits are information bits or parity bits. Also, care has to be taken that interleaving does not mix too many information bits that are to be used together for correction in the same modulation vector. This requires particular care in the case of turbo-codes, where the information bits and parity bits are related in several different ways due to interleaving prior to parity bit generation.

Taking such care becomes even more difficult when the puncturing rate is adapted dynamically to support a required quality of service.

Accordingly it is, among others, an object of the invention to provide for an apparatus with an error correcting encoder that uses variable rate puncturing and interleaving after parity generation in which modulation with proper gray labeling is simplified.

The invention provides for an apparatus as set forth in claim 1. According to the invention the interleaving for protection against burst errors is performed after generation of parity symbols, but effectively before puncturing. The rate of puncturing is dynamically adapted, for example dependent on the required quality of service. The punctured symbols are used to modulate a transmission signal. A predetermined interleaving scheme is used, not adapted to the selected rate of puncturing. Generally, the information symbols will also be interleaved as part of the interleaving scheme to protect against burst errors, but these information symbols need not be punctured. A predetermined interleaving scheme with sufficient protection against burst errors can be used. As a result the interleaving of parity symbols do not interact puncturing to have a complex effect on modulation. None of the interleaving scheme needs to depend on the rate of puncturing.

In an embodiment interleaving is performed using interleaving memory, the parity symbol generator writing the parity symbols into the interleaving memory. The modulator maps the parity symbols to positions in modulation symbols according to the locations at which the parity symbols have been written into the memory. By using an interleaving scheme that determines the relation between the locations where respective output symbols of the parity generators are written and the locations from which symbols for use at certain positions are read related parity symbols and information symbols are distributed over separated modulation symbols. In an embodiment several sets of parity symbols are generated, a first set by convolution of incoming information symbols in their original order and a second set by convolution of the incoming information bits in permuted order. In this embodiment the information symbols and the parity symbols from the first set are interleaved with a first interleaving scheme and the parity symbols from the second set are interleaved with a second interleaving scheme, both prior to puncturing. By keeping the interleaving of the second set apart a minimum of additional latency is added to the second set, which already has a latency due to the permutation prior to generation of the parity symbols.

Receivers of modulated signals can be adapted accordingly, so that the interleaving scheme does not depend on variations in the rate of puncturing.

These and other objects and other advantageous aspects of the apparatuses and methods according to the invention will be described in more detail using the following figures.

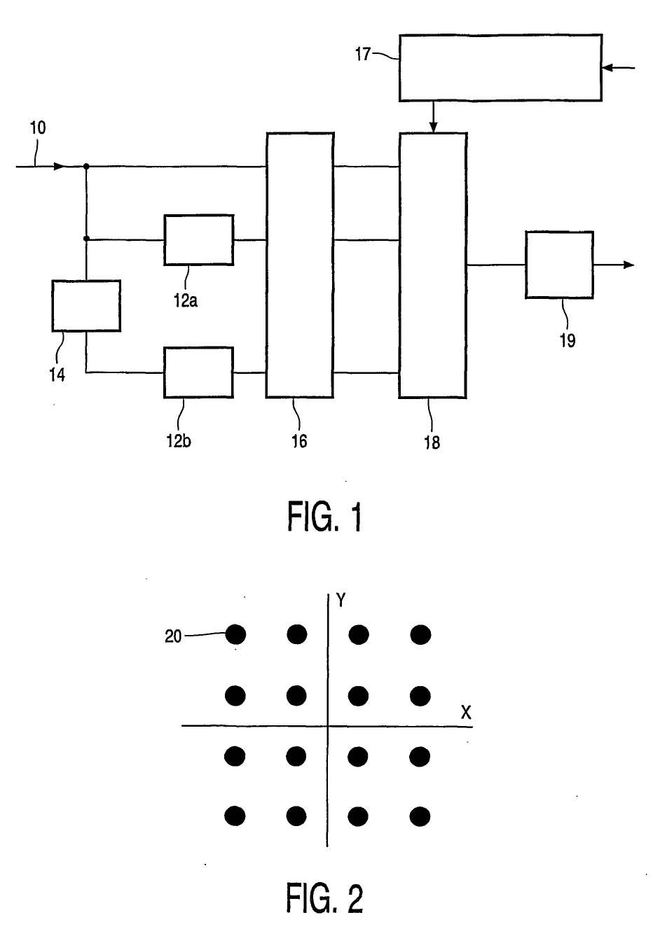

FIG. 1 shows an apparatus with an encoder

FIG. 2 illustrates modulation

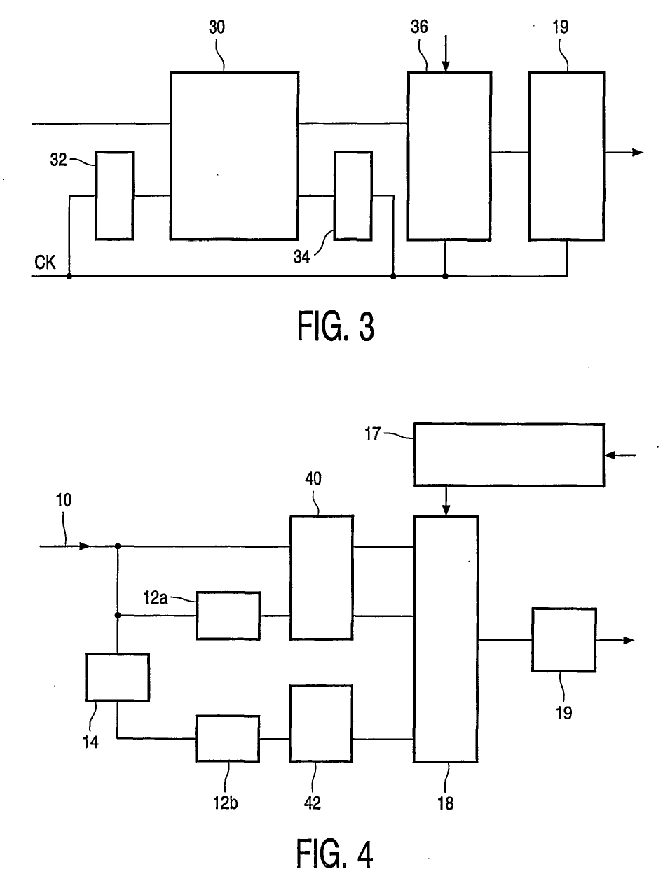

FIG. 3 shows a an interleaver and a puncturer

FIG. 4 shows a further apparatus with an encoder

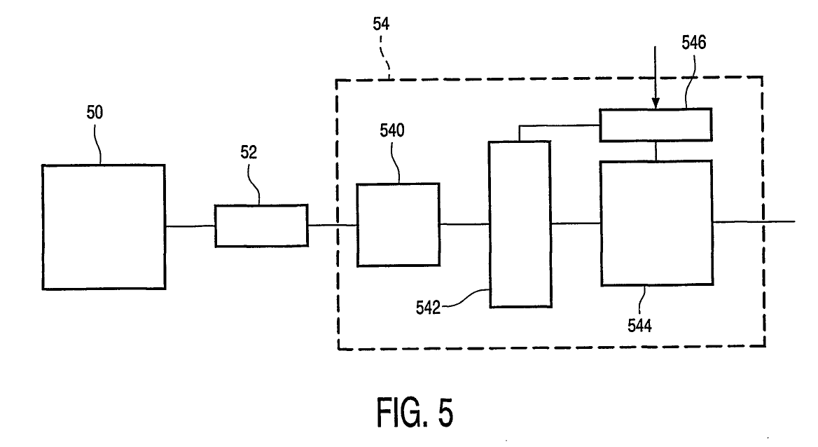

FIG. 5 shows a transmission system

FIG. 1 shows an apparatus with a turbo encoder. The apparatus has an input 10 and contains convolution encoders 12a,b, a first interleaver 14, a second interleaver 16, a coding rate control unit 17, a puncturer 18 and a modulator 19. Input 10 is coupled to second interleaver 16 directly, via a first one of the convolution encoders 12a, and via a series connection of first interleaver and a second one of the convolution encoders 12b. Second interleaver 16 has outputs coupled to puncturer 18, which has an output coupled to modulator 19. Coding rate control unit 17 has an output coupled to a control input of puncturer 18.

In operation convolution encoders 12a,b and first interleaver 14 perform turbo-encoding in a way that is known per se. That is, they produce parity bits to supplement information bits that are received at input 10. Generally speaking, encoding may alternatively involve information symbols and parity symbols, each of which may require a plurality of bits to represent, but in the following the invention will be described for information bits and parity bits, it being understood that the invention applies to symbols as well.

The first one of the convolution encoders 12a computes first parity bits as a convolution of the stream of information bits that arrives at input 10. First interleaver 14 interleaves (permutes the sequence of) the stream of information bits that is received at the input. The second one of the convolution encoders 12b computes second parity bits as a function of the interleaved stream. Although a turbo-coder has been illustrated that generates two streams of parity bits, it will be understood that the invention applies to any encoder that produces parity bits, for example an encoder with more than two convolution encoders, each applied to a differently interleaved stream of information bits.

Second interleaver 16 and puncturer 18 feed the information bits and the parity bits to modulator 19. Modulator 19 modulates the information bits and the parity bits onto a transmission signal. The transmission signal may be transmitted for example with radio frequency wireless transmission, but of course the invention may also be applied when transmission is via any other kind of channel, e.g. via temporary of permanent storage of the modulated signal in a medium, such as a magnetic storage device.

As an example of modulation FIG. 2 illustrates how a QAM signal is modulated. In successive modulation cycles the modulation of the QAM signal is described by successive modulation vectors (phase and amplitude of the transmission signal; only one vector 20 being indicated a reference sign for the sake of clarity). The figure shows a constellation of sixteen possible modulation vectors 20 that can be used. In each modulation cycle four bits (information bits and/or parity bits) select which vector is used. This is done with gray labeling, that is, in a way so that neighboring ones vectors 20 correspond to values of the four bits that differ only in one bit. As a result a demodulation error that confuse neighboring vectors, which is the most probable type of error, will result only in one erroneous bit. This may be realized for example by using two of the four bits to select the coordinate of the vector 20 along the Y axis and the remaining two bits to select the coordinate of the vector along the X-axis, successive vectors along the axis being selected by the values 00, 01, 11, 10 of the relevant bits successively. It should be appreciated that the sixteen vector constellation of FIG. 2 is merely an example: in practice larger constellations of for example 8×8 vectors may be used.

Preferably the relation between the values of the bits and the vectors in the constellation is selected so the bit that differs between two bit patterns that correspond to neighboring vectors 20 is a parity bit. As a result a demodulation error that confuse neighboring vectors, which is the most probable type of error, is more likely to result in a parity bit error than in an information bit error, which is more difficult to correct.

The invention is not limited this type of QAM modulation, or indeed to QAM modulation. The relevant point for the invention is that modulator 19, at least to some extent, has to treat information bits and parity bits differently. Therefore modulator 19 should be able to distinguish at least some of the parity bits and the information bits.

Second interleaver 16 interleaves the information bits and the first and second parity bits. This is done in anticipation of modulation and transmission, so that information bits and parity bits that may be used together to correct errors are modulated in different modulation cycles that are separate form one another by a longer time than the duration of typical burst errors during transmission. Burst errors can cause a large number of bit errors. Because of the interleaving by second interleaver 16 these errors will be distributed so that individual ones of the errors, or small numbers of the errors can be corrected independently of one another.

Coding rate control unit 17 receives a control signal that indicates the required coding rate. The coding rate may be selected for example as a function of a measured error rate during transmission, or dependent on a level of protection against errors that is needed for the specific information that is being transmitted, or dependent on the available bandwidth. Dependent on the selected coding rate coding rate control unit 17 supplies a control signal to puncturer 18.

Puncturer 18 selectively passes parity bits from second interleaver 16 to modulator 19. The fraction of the parity bits that puncturer 18 passes determines the coding rate. Accordingly, puncturer 18 adjusts the selection of the parity bits dependent on the control signal from coding rate control unit 17, so that the required fraction of parity bits is passed to modulator 19. The more of the parity bits are passed, the better the error protection, at the expense of a higher bandwidth need.

FIG. 3 shows an embodiment of the interleaver and puncturer. The embodiment contains a multiport memory 30, a first and second addressing unit 32, 34 and a puncturer 36 (multiport memories are known per se. They may be realized for example using a single port memory attached to a multiplexing bus structure). A first port of memory 30 has a data input coupled to at least the output of the parity bit generators (not shown). For the sake of clarity only a single input is shown, but it should be understood that this input may connect to multiple parity bit generators (e.g. via a multiplexer, not shown) and also the input for information bits. An address input of the first port is coupled to first addressing unit 32. A second port of memory 30 has a data output coupled to puncturer 36 (here too only a single connection is shown for the sake of clarity). Second addressing unit 34 is coupled to the address input of the second. First addressing unit 22, second addressing unit 34, puncturer 36 and modulator 19 are clocked with a system clock CK.

In operation at least parity bits are supplied to the data input of the first port of memory 30 during successive clock cycles, but preferably both parity bits and information bits are supplied. First addressing unit supplies addresses for storing these parity bits, for example in an increasing order of addresses A(i)=base+(i mod I), (i=0, 1,2 . . . ) that wraps around after a number I of clock cycles. Second addressing unit 34 generates a permuted series of addresses to read the parity bits (and preferably also the information bits) from memory 30 in a different order than in which they were written to interleaved at least the parity bits. An example of the sequence of addresses uses as jth address A(j) (i=0, 1, 2 . . . )
A(j)=base+[(d*j+a) mod I]

Where “I” is an interleaving block size, “d” is a step size which is relatively prime with I (d and I have no common divisor other than 1), and moreover d+1 is smaller than the square root of two times I, “a” and “base” are offset that may be selected arbitrarily. In this way parity bits that have been written at adjacent locations are distributed, with a distance d between the indices j used during reading. When used in modulation symbols indexed by “j “, burst errors with lengths that correspond to less than d can be corrected. (It will be understood that the particular formula for A(j) is shown merely by way of example. Many other formulas for interleaving are known per se). Puncturer 36 selects a subset of the parity bits that it receives from memory 30 and supplies these only the selected parity bits to modulator 19 for use in modulation. Interleaving need not be adapted to changes in the fraction of parity bits that is selected, for example the block size I and the distance d need not be changed. (Of course in fact an arbitrary change of interleaving, such as a change in code size I and/or distance d may be applied, but this change does not depend on the selected fraction of parity bits).

It will be understood that the embodiment of FIG. 3 is merely given by way of example. Other embodiments may be used instead, for example an embodiment wherein puncturer 36 does not receive all parity bits, but emits addresses for those parity bits that will be used by modulator 19 (skipping the parity bits that are punctured). In this case, second addressing unit 34 may be replaced by an addressing unit that maps addresses “j” from puncturer 36 to the interleaved addresses A(j) for memory 30. As another alternative, first addressing unit 32 may supply addresses for writing parity bits into memory 30 in an interleaved sequence (the inverse of A(j)), puncturer 36 addressing the selected parity bits without address translation (with address “j”). Also both writing into memory 30 and reading from memory 30 may involve a form of interleaved addressing.

In each case the way that the addresses are determined does not depend on the particular coding rate selected by coding rate control unit 17. That is, each parity bit is interleaved with the other parity bits in a predetermined way, selection of those parity bits that are actually used (omitting punctured parity bits) being performed by selecting according to the position “j” of the parity bit in the interleaved order A(j).

Although the functional description of the encoding process is that addressing units 32, 34, combined with memory 30 take care of interleaving, and that puncturer 36 takes care of puncturing, the modulator taking care of modulation, these functions may of course be distributed differently. For example, reading from memory 30 may be driven by modulator 19, the modulator requesting parity bits from the interleaver, either using addresses according to the particular position in the vectors of the modulation cycles in which the parity bit is to be used or by requesting the parity bits for different positions sequentially in a fixed order. In this case the function of puncturer 36 may be included in modulator 19, modulator 19 selecting which parity bits to use and which not to use, and supplying the addresses of each particular selected parity bits to memory 30 when modulator needs the particular bit. As an alternative puncturer 36 may translate the requests for addressed bits from modulator 19 into addresses for memory (possibly subject to further translation by second addressing unit 34), in a way that skips some parity bits that are punctured, and supply the addresses to memory.

Also, although the invention has been described using bits (information bits and parity bits) as the basic units of encoding, interleaving and modulation, the invention can of course be applied using larger units of manipulation, such as n-bit words. Bits or such larger units will both be referred to as symbols. The invention applies interleaving of such symbols prior to puncturing of these symbols and modulation of combination of these symbols.

Memory 30 may use double buffering, wherein one memory area is used to write parity bits and another area is used to read parity bits, the roles of the areas being periodically swapped. But a single area may be used instead, if a proper addressing scheme is used. A single memory 30 may be used to interleave the parity bits as well as the information bits. In this case, a multiplexer may be used to collect these bits from different sources. Alternatively, separate memories (not shown), or independently addressed different memory ranges may be used for interleaving information bits on one hand and parity bits on the other hand, or even for different sets of parity bits.

FIG. 4 shows a further apparatus with an encoder. In this further apparatus two second interleavers 40, 42 are used after parity bit generation. A first one of the second interleavers 40 receives and interleaves information bits and parity bits from the convolution encoder 12a that convolutes non-interleaved information bits. A second one of the second interleavers 42 receives and interleaves parity bits from the convolution encoder 12b that convolutes interleaved information bits.

The advantage of splitting the second interleaver is that latency is reduced. Interleavers introduce latency in proportion to the number of bits involved. The total latency is reduced by involving a smaller number of bits in the second one of the second interleavers 42, which processes the parity bits that already have additional latency because of interleaving by first interleaver 14 prior to parity bit generation.

FIG. 5 shows a transmission system, comprising an encoder/modulator 50, a channel 52 and a decoder 54. Decoder 54 comprises a demodulator 540, a de-interleaver 542 and an error correction unit 544 in series with one another. A rate control unit 546 controls error correction unit and de-interleaver dependent on a puncture rate. Channel 52 may have any nature: it may be the ether, in case of wireless transmission or it may be a storage medium on which the modulated signal is stored, for example. Encoder 50 is of a type that applies a predetermined type of interleaving information and parity bits prior to puncturing, for example an encoder of the type shown in FIG. 1 or 4.

In operation, demodulator 540 demodulates information bits and parity bits from the transmitted signal. De-interleaver 542 de-interleaves the information bits and parity bits and error correction unit 544 corrects errors in the information bits, as far as possible. A predetermined de-interleaving scheme is used, independent of the rate of puncturing, using dummy bits at the positions of parity bits that have been punctured. De-interleaver 542 comprises a memory in which at least the parity bits are written and from which these parity bits are read to perform de-interleaving. Bach parity bit is written at a predetermined location according to its relation to other parity bits and information bits in the error correcting code. Rate control unit 546 signals to de-interleaver 542 which locations have to be skipped or filled with dummy bits, because the corresponding parity bits have been suppressed by puncturing. Subsequently encoder reads the parity bits from memory in de-interleaved form.

1. A device for operating a high-pressure discharge lamp, comprising:
a switched-mode power supply circuit for supplying power to the high-pressure discharge lamp from a supply voltage, the power supply circuit comprising at least one power switching element;
control means for controlling the at least one power switching element in its switched-on and switched-off states for controlling the power or current supplied to the high-pressure discharge lamp;
wherein the control means are adapted to control the power consumed by the lamp during its steady phase or the current consumed by the lamp during its run-up phase by controlling the on-time (Ton) of the switched-on state of the at least one power switching element.

2. A device according to claim 1, wherein the value of the on-time (Tₒₙ) of the at least one power switching element is a preset value, the preset value depending on the specifications of the type of discharge lamp used.

3. A device according to claim 1, wherein the on-time (Tₒₙ) of the at least one power switching element for a specific discharge lamp type is substantially constant.

4. A device according to claim 1, comprising:
input current determining means for determining the input current of the power supply, the input current determining means providing a signal representative of the determined input current;
a feedback means through which said signal is fed back to the control means, wherein the control means are adapted to control the on-time (Tₒₙ) of the at least one switching element as a function of said feedback signal.

5. A device according to claim 1, comprising
voltage determining means for determining the lamp voltage, the voltage determining means providing a signal representative of the determined lamp voltage,
a feedback means through which said signal is fed back to the control means;
wherein the control means are adapted to control the on-time (Tₒₙ) of the at least one power switching element as a function of said feedback signal.

6. A device according to claim 1, comprising a dim level means for setting a reduced lamp power level, the dim level means providing a signal representative of the dim level of the lamp,
wherein the control means are adapted to control the on-time (Tₒₙ) of the at least one power switching element as a function of said signal.

7. A device according to claim 5, wherein the control means comprise a feedback controller for controlling the control means.

8. A device according to claim 7, wherein the control means are adapted to provide fast lamp power adjustments and the feedback controller is adapted to provide relatively slow lamp power adjustments.

9. A device according to claim 4, wherein the on-time (Tₒₙ) is iteratively adapted with a iteration frequency lower than the switching frequency of the switched-mode power supply.

10. A device according to claim 1, wherein the switching frequency of the switched-mode power supply is at least 100 kHz.

11. A device according to claim 9, wherein the iteration frequency is 100 Hz or less, preferably about 10 Hz or less.

12. A device according to claim 1, wherein use is made of a half or full-bridge power supply and a filter circuit comprising a series inductor (L) and at least one filter capacitor (C) parallel to the lamp.

13. A device according to claim 1, wherein the switched-mode power supply comprises a half-bridge or full-bridge commutating forward topology.

14. A device according to claim 1, wherein the switched-mode power supply comprises a down-converter

15. A method of operating a high-pressure discharge lamp, comprising:
supplying power to the high-pressure discharge lamp from a supply voltage, using at least one power switching element;
controlling the power consumed by the lamp during its steady phase using control means;
wherein said control means control the lamp power during the steady state of the lamp by fixing the on-time (Tₒₙ) of the at least one power switching element.

16. A method according to claim 15, comprising presetting the value of the on-time (Tₒₙ) of the at least one power switching element depending on the specifications of the type of discharge lamp used.

17. A method according to claim 15, wherein the on-time (Tₒₙ) of the at least one power switching element is kept substantially constant.

18. A method according to claim 15, comprising determining the lamp voltage, providing a signal representative of the determined lamp voltage, feeding said signal back to the control means and adapting the on-time (Tₒₙ) of the at least one power switching element as a function of the determined lamp voltage.
